(19) United States
(12) Patent Application Publication
(10) Pub. No.: US 2020/0212240 A1
(43) Pub. Date: Jul. 2, 2020

(54) LUMINESCENT SOLAR CONCENTRATOR USING PEROVSKITE STRUCTURES

(71) Applicant: GLASS TO POWER S.P.A., Rovereto (TN) (IT)

(72) Inventors: Sergio BROVELLI, Milano (IT); Francesco MEINARDI, Lecco (IT)

(73) Assignee: GLASS TO POWER S.P.A., Rovereto (TN) (IT)

(21) Appl. No.: 16/643,199

(22) PCT Filed: Sep. 6, 2018
(86) PCT No.: PCT/IB2018/056807

§ 371 Date: Feb. 28, 2020

(30) Foreign Application Priority Data
Sep. 13, 2017 (IT) 102017000102364

(51) Int. Cl. H01L 31/055; C09K 11/74; C09K 11/06

(52) U.S. Cl. CPC H01L 31/055; C09K 11/06; C09K 11/7435

(57) ABSTRACT

A luminescent solar concentrator having a glass or plastics matrix containing or covered with perovskites having luminescence from intra-gap states is provided.

The present invention relates to a luminescent solar concentrator according to the precharacterising clause of the principal claim.

As is known, luminescent solar concentrators (or LSC) comprise a glass or plastics matrix or waveguide defining the body of the concentrator coated or doped with highly emissive elements or components commonly referred to as fluorophores. Direct and/or diffuse sunlight is absorbed by such fluorophores and readmitted at a longer wavelength. The luminescence so generated propagates towards the edges of the waveguide through total internal reflection and is converted into electrical energy by high-efficiency photovoltaic cells attached to the perimeter of the body of the concentrator.

Luminescent solar concentrators have recently been proposed as an effective supplement to conventional photovoltaic modules for the construction of building-integrated photovoltaic (or BIPV) systems, such as for example semi-transparent photovoltaic windows that are potentially capable of converting the facias of buildings into electrical energy generators. These LSCs offer a number of advantages due both to the optical functioning mechanism and their design/manufacturing versatility; in fact: i) by collecting sunlight over an extensive area the conformation of the LSCs, which is usually plate- or sheet-shaped, generates an appreciable incident luminous density on the perimetral photovoltaic devices giving rise to high photocurrents; ii) because LSCs use smaller quantities of photovoltaic material for optical-electrical conversion, they make it possible to use photovoltaic devices with higher efficiency than conventional silicon cells, which being expensive to construct would be expensive to use in large quantities; iii) indirect illumination of the perimetral photovoltaic cells by the waveguide renders LSCs essentially unaffected by efficiency losses and harmful electrical stresses due to partial shading of the device, which instead occurs with conventional photovoltaic modules, iv) LSCs can be manufactured with unequalled freedom in terms of shape, transparency, colour and flexibility and through their design solar energy can be collected through semitransparent waveguides without electrodes, having an essentially zero aesthetic impact, making them ideally suitable for building glazing systems and possibly providing architects with a tool for further increasing the aesthetic value of a building.

Despite this promise, the widespread use of LSCs has for a long time been hindered by a lack of fluorophores with a sufficiently small spectral overlap between their absorption and emission profiles to suppress reabsorption of the guided luminescence, which results in serious optical losses in large-sized devices. This is due to both the probability of non-radioactive decay, which falls exponentially with the number of re-radiation events and the isotropic nature of the emission process, which makes the direction of propagation of the guided light a causal factor, increasing the number of emitted photons striking the surface of the LSC outside the critical total internal reflection angle dictated by Snell's physical law.

In order to obtain efficient LSCs the fluorophores must have high luminescence efficiency and the greatest possible energy separation between their own absorption and optical emission spectra (or the term “Stokes shift”). This requirement is essential for the manufacture of large-scale concentrators in which the light emitted by a given fluorophore must traverse relatively large distances before reaching the edge of the body of the concentrator (generally but not exclusively being layer- or sheet-like in shape).

Perovskite nanostructures (hereinafter also indicated by NS) based on lead halides, both in their hybrid organic-inorganic MAPbX3 (MA=CH₃NH₃; X=Cl, Br, I) chemical composition and in the completely inorganic form of lead and caesium halides (CsPbX₃), have recently emerged as potential candidates in a variety of optoelectronic and photon technologies, extending from photovoltaic cells to diodes and lasers. Like known chalcogenide nanostructures, the optical properties of perovskite NS can be adjusted by controlling dimensions, shape and composition, which can easily be varied through post-synthesis halogen exchange reactions; through these emission spectra across the entire visible spectrum can be obtained.

The spectral separation between the optical absorption and the luminescence of said conventional perovskite nanostructures of both the CsPbX₃ and MAPbX₃ type is however very small, which results in great losses of efficiency in LSCs.

Again for this reason, no studies on the application of perovskite NS having a small spectral overlap between absorption and optical emission to LSCs have been reported in the literature.

The object of the present invention is to provide a luminescent solar concentrator or LSC which is improved in comparison with known solutions and those disclosed but still at the investigation stage for practical application.

In particular, one object of the present invention is to provide a luminescent solar concentrator having high efficiency, or a luminescent solar concentrator having very small or in any event negligible if not zero optical losses due to reabsorption.

The solar concentrator according to the invention comprises perovskite NS. Despite the disadvantages of these nanostructures indicated above, the doping of perovskite NS has recently been achieved using a variety of transition metal atoms, including manganese, cadmium, zinc and tin, which in the case of Mn (and bismuth in macroscopic crystals) result in luminescence due to intra-gap electron states introduced by the doping agent, with high spectral separation from the absorption band of the NS containing it (hereinafter indicated as “host NS”) and sensitising its emission. By making it possible to uncouple the host NS optical absorption from the intra-gap emission of the hosted impurities, the doping process appreciably increases the application potential of perovskite nanostructures, both in the form of nanocrystals (zero, one and two-dimensional) and thin layers (known as “layered perovskites”), opening the way for their use in LSCs. Other strategies for widening spectral separation which do not necessarily require doping with heteroatoms comprise the use of alternative compositions, such as for example those of caesium and tin halides (CsSnX₃), in which intra-gap emission states not due to the presence of heteroatoms occur.

These and other objects which will be apparent to those skilled in the art are accomplished through a luminescent solar concentrator according to the appended claims.

For a better understanding of the present invention the following drawings are appended purely by way of anon-limiting example, and in these:

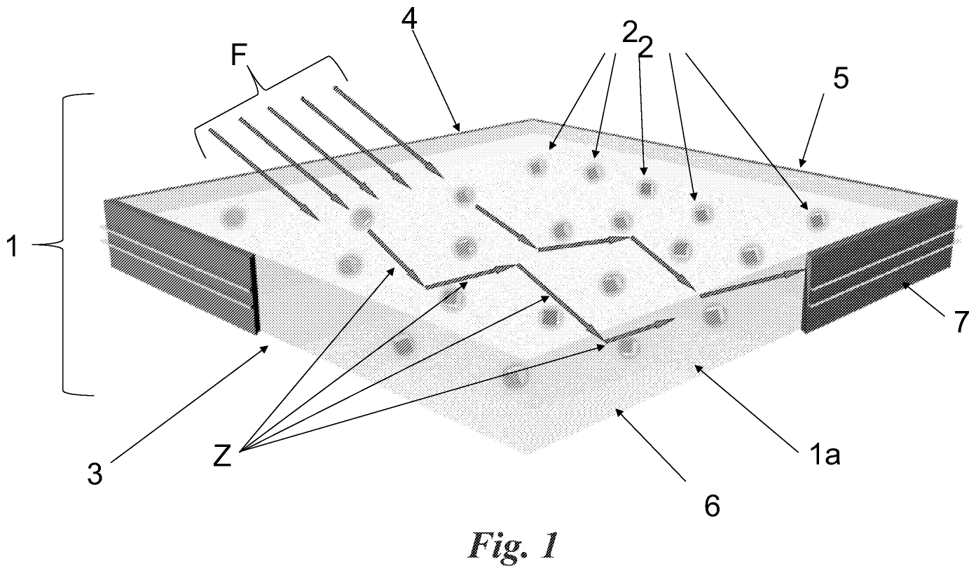

FIG. 1 shows a diagrammatical representation of a luminescent solar concentrator (LSC) comprising a polymer matrix incorporating perovskite nanocrystals doped with heteroatoms or having a suitable composition for obtaining intra-gap states which are not due to heteroatoms;

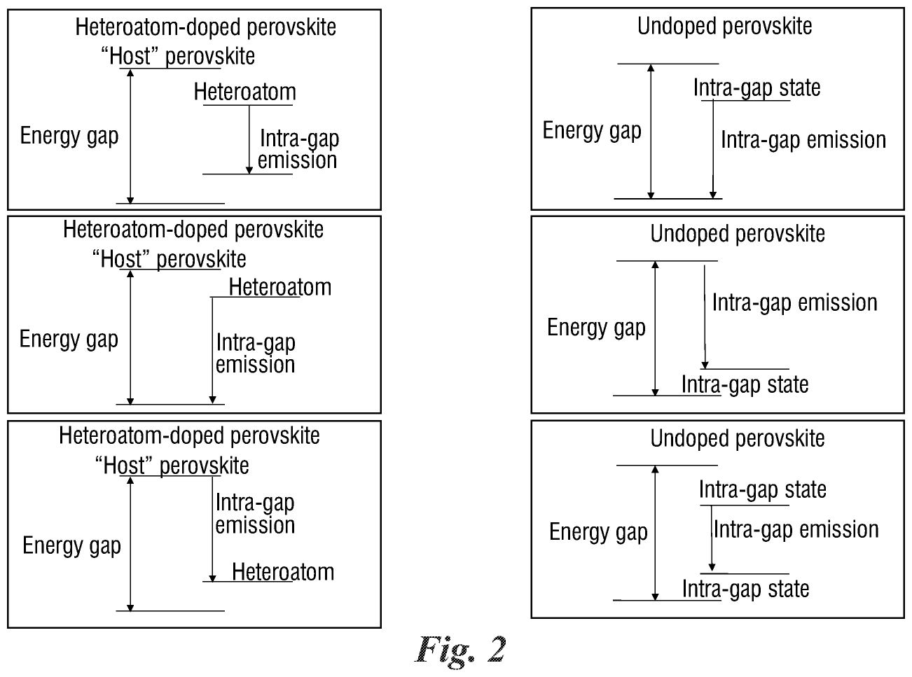

FIG. 2 shows a comparison between a diagram representing the energy levels of an undoped perovskite nanostructure and those of a perovskite nanostructure doped with a heteroatom (for example manganese) and of a composition such as to have optically active intra-gap energy levels, of both the donor and accepter type, used in an LSC according to the invention;

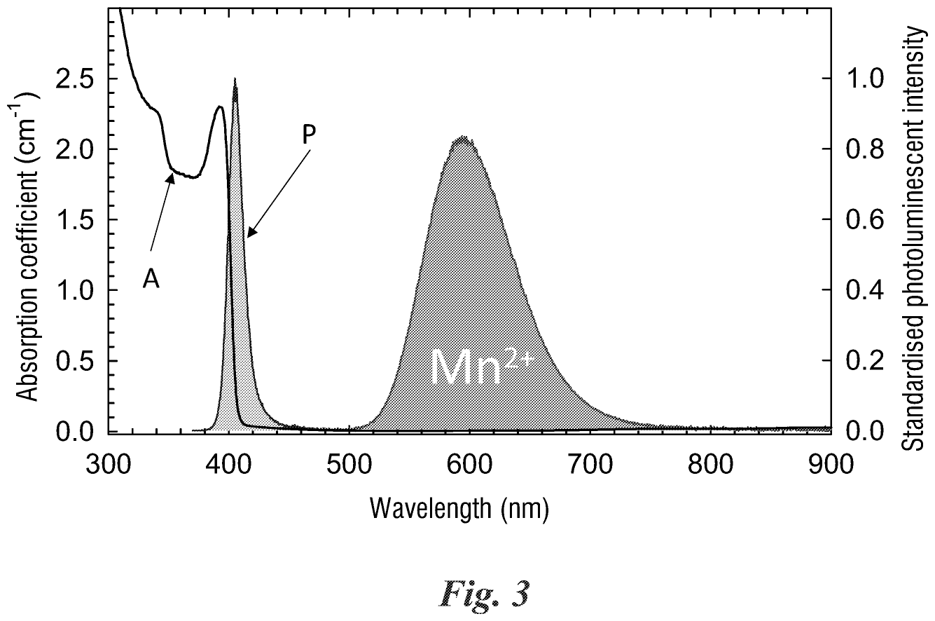

FIG. 3 shows the absorption spectrum (line A) and the photoluminescence spectrum (line P) of particular perovskite nanocrystals obtained according to the manner of implementation of the invention described;

FIG. 4 shows standardised luminescence spectra for the perovskite nanocrystals considered in FIG. 3 collected at the edges of a luminescent solar concentrator according to one embodiment of the invention; and

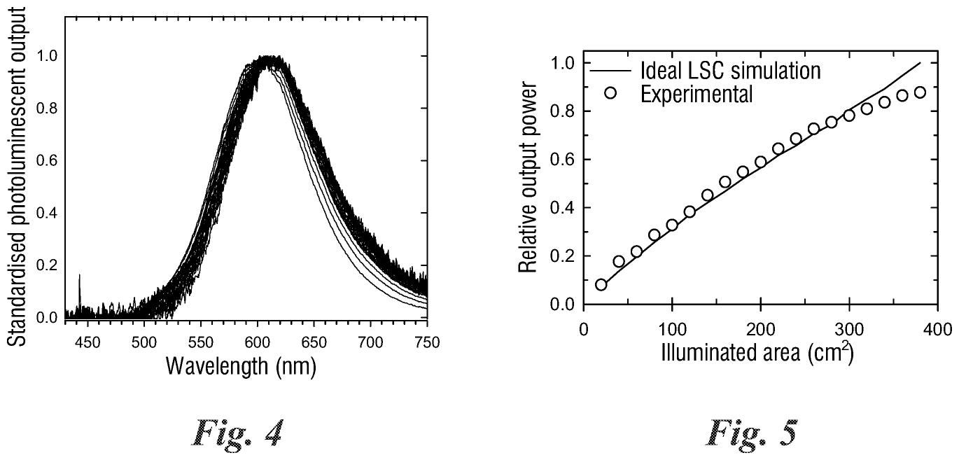

FIG. 5 shows the output power produced by photovoltaic cells located at the edges of the concentrator according to the invention.

With reference to the figures mentioned, a luminescent solar concentrator or LSC 1 comprises a body 1A made of glass or plastics or polymer material in which colloidal nanocrystals of perovskite are present, which for purely descriptive purposes are shown as clearly identifiable elements within body 1 of the concentrator. As is known, a nanocrystal or nanostructure is a structure having linear dimensions of the order of a nanometre (for example 10 nm) and in any event less than 100 nm. The nanocrystals or nanostructures NS present in LSC 1 are indicated by 2.

At the edges 3,4, 5,6 of body 1 there are photovoltaic cells 7 capable of collecting and converting the light radiation emitted by the NS present in body 1 (indicated by arrows Z) into electricity. The incident solar radiation on the body of the device is indicated by arrows F.

Body 1A of LSC 1 may be obtained from different materials. By way of a non-limiting example the latter may be: polyacrylates and polymethyl methacrylates, polyolefins, polyvinyls, epoxy resins, polycarbonates, polyacetates, polyamides, polyurethanes, polyketones, polyesters, polycyanoacrylates, silicones, polyglycols, polyimides, fluorinated polymers, polycellulose and derivatives such as methyl-cellulose, hydroxymethyl-cellulose, polyoxazine, silica-based glasses. The same body of the LSC may be obtained using copolymers of the abovementioned polymers.

The NS are able to exhibit photoluminescence efficiencies of almost 100% and an emission spectrum which can be selected through dimensional control and through composition or doping with heteroatoms, as a result of which they can be optimally incorporated into various types of solar cells comprising both single junction and multiple junction devices.

According to a fundamental characteristic of the present invention the colloidal nanostructures used as emitters or fluorophores in the LSC described are, purely by way of non-limiting example, perovskite NS having generic compositions of the type: 1) M¹M²X₃ (with M¹=Cs, M²=Pb, X=element in group VII_{A} or 17 in the IUPAC nomenclature) doped with heteroatoms; 2) M¹M²X₃ (with M¹=Cs, M²=Sn or another element in group IV or 14 in the IUPAC nomenclature other than Pb; X=element in group VII_{A} or 17 in the IUPAC nomenclature) which are not doped or doped with heteroatoms; 3) M¹₂M²X₆ (with M¹=Cs, M²=element in group IV or 14 in the IUPAC nomenclature, X=element in group VII_{A} or 17 in the IUPAC nomenclature) either undoped or doped with heteroatoms; 4) MAM²X₃ (with MA=[CH₃NH₃]+, [CH(NH₂)₂]+, [CH₆N₃]+; M²=element in group IV or 14 in the IUPAC nomenclature, X=element in group VII_{A} or 17 in the IUPAC nomenclature) either undoped or doped with heteroatoms; 5)M¹₃M²₂X₉ or MA₃M²₂X₉ (with M¹=Cs or another element in group IA or 1 in the IUPAC nomenclature, M₂=Bi or another element in group V_{A} or 15 in the IUPAC nomenclature) undoped or doped with heteroatoms; 6) double perovskites of generic composition M¹₂M²M³X₆ (with M1=an element in group IA or 1 in the IUPAC nomenclature, M²=elements in group IB or 11 in the IUPAC nomenclature or group IIIA or 13 in the IUPAC nomenclature, M³=element in group V_{A} or 15 in the IUPAC nomenclature, X=element in group VII_{A} or 17 in the IUPAC nomenclature) such as, for example: Cs₂CuSbCl₆, Cs₂CuSbBr₆, Cs₂CuBiBr₆, Cs₂AgSbBr₆, Cs₂AgSbI₆, Cs₂AgBiI₆, CsₛAuSbCl₆, Cs₂AuBiCl₆, Cs₂AuBiBr₆,

Cs₂InSbCl₆, Cs₂InBiCl₆, Cs₂TlSbBr₆, Cs₂TlSbI₆, and Cs₂TlBiBr₆. These structures may be undoped or doped with heteroatoms; 7) structures of the type (C₄N₂H₁₄Br) ₄SnX₆ (with X=Br, I or another element in group VII_{A} or 17 in the IUPAC nomenclature).

In a case reported by way of example and to which FIGS. 2-5 refer, CsPbCl₃ was specifically selected as the host material and manganese ions (Mn²⁺) as the doping agent, because in this system both the ground state (⁶A₁) and the excited triplet state (⁴T₁) of Mn²⁺ lie within the NS host energy gap, which results in more effective sensitisation of the doping agent by the NS host in comparison with all the other varieties of CsPbX₃ having pure compositions and compositions mixed with halogens. What is fundamental for application in LSCs is the fact that the ground state and the excited states of Mn²⁺ have a multiplicity of different spins, determining the characteristic small extinction coefficient (approximately 1 M⁻¹ cm⁻¹) of the ⁶A₁→⁴T₁ absorption transition. This means that the corresponding luminescence indirectly excited by the host NS is essentially unaffected by reabsorption.

In one embodiment of the invention a nanocomposite LSC comprising a bulk-polymerised polyacrylate matrix incorporating perovskite NS of the abovementioned type was prepared and tested. Spectroscopic measurements of the NS in toluene solution and incorporated in the polymer wave guide indicate that the optical properties of the doping agent are completely preserved after the free-radical polymerisation process, further demonstrating the suitability of doped perovskite NS as emitters in nanocomposites of plastics material. Finally, light propagation measurements performed on the LSC confirm that the LSC device based on perovskite NS doped with Mn²⁺ essentially behaves as an ideal device without reabsorption or optical diffusion losses.

In one embodiment of the invention nanocrystals of CsPbCl₃ perovskite with a Mn doping level of approximately 3.9% were used.

FIG. 3 shows the optical absorption spectrum (line A) and the photoluminescence spectrum (PL, graph P) of the nanocrystals with the characteristic absorption peak at approximately 395 nm and the corresponding narrow band photoluminescence at approximately 405 nm, representing approximately 20% of the total emission. The remaining 80% of the emitted photons are due to the ⁴T₁→⁶A₁ optical transition of the Mn²⁺ doping agents, which give rise to the peak at approximately 590 nm, with a consequent high Stokes shift of approximately 200 nm (approximately 1 eV) from the absorption edge of the CsPbCl3 host nanocrystal.

Examination of the spectrum in FIG. 4 shows that the luminescence of the Mn²⁺ is almost completely uninfluenced by reabsorption by the host nanocrystal.

By way of example, a luminescent solar concentrator or LSC 1 was constructed using bulk polymerisation with free radical initiators of a mixture of methylmethacrylate (MMA) and lauryl methacrylate (LMA) doped with nanocrystals having a percentage by weight of 80% of MMA and 20% of LMA (obviously other percentages by weight are possible).

LSC 1 was obtained with dimensions of 25 cm ×20 cm×0.5 cm and comprising 0.03% by weight of nanocrystals.

FIG. 4 shows the standardised luminescence spectra for manganese emission in CsPbCl₃ nanocrystals collected from photovoltaic cells 7 present at the edges of the luminescent solar concentrator under local excitation at an increasing distance from the edge of the sheet. The spectra are essentially identical, indicating that there are no distortional effects due to optical absorption.

Further confirmation of the absence of reabsorption and optical diffusion losses in the LSC is provided by the fact that all the portions of the surface of the device contribute almost equally to the total power collected at its edges. To show this behaviour FIG. 5 shows the relative output power extracted from one of the edges of the LSC (edge dimensions having an area of 20×0.5 cm²) measured using calibrated crystalline Si solar cells attached to one edge of the sheet and progressively exposing increasingly larger portions of the area of the LSC to solar radiation.

FIG. 5 shows a graph or line C relating to a theoretically calculated power for an ideal LSC without diffusion or reabsorption losses and having identical dimensions to the one constructed experimentally (25 cm×20 cm×0.5 cm); said ideal LSC includes emitters having the same quantum emission yield of the Mn²⁺ used in the nanocrystals of LSC 1. For the ideal LSC the output optical power is determined exclusively by the numerical aperture of the illuminated area. The experimental data, also shown in FIG. 5, almost perfectly overlap with the calculated data.

Thanks to the invention the suitability of perovskite nanostructures with emission from intra-gap states due in the case in the example to the use of doping agents as emitters with virtually zero reabsorption in luminescent solar concentrators has been demonstrated.

1. A luminescent solar concentrator having a body of polymer or glass material and comprising fluorophores, wherein said fluorophores are perovskite nanostructures doped or not doped with heteroatoms, with emission from intra-gap states.

2. The luminescent solar concentrator according to claim 1, wherein said nanostructures are alternatively of nanocrystalline, filament or two-dimensional or thin film shape.

3. The luminescent solar concentrator according to claim 1, wherein the perovskite nanostructures alternatively have compositions of the following type:
A) M¹M²X₃ where:
M¹=an element in group IA or 1 in the IUPAC nomenclature;
M²=Pb; X=element in group VII_{A} or 17 in the IUPAC nomenclature, doped with heteroatoms;
B) M¹M²X₃ where:
M¹=element in group IA or 1 in the IUPAC nomenclature,
M²=element in group IV or 14 in the IUPAC nomenclature other than Pb;
X=element in group VII_{A} or 17 in the IUPAC nomenclature, undoped or doped with heteroatoms;
C) M¹₂M²X₆ where:
M¹=element in group IA or 1 in the IUPAC nomenclature;
M²=element in group IV or 14 in the IUPAC nomenclature;
X=element in group VII_{A} or 17 in the IUPAC nomenclature, either undoped or doped with heteroatoms;
D) MAM²X₃ where:
MA=[CH₃NH₃]⁺, CH(NH₂)₂]⁺, [CH₆N₃]⁺ or another organic cation;
M²=element in group IV or 14 in the IUPAC nomenclature;
X=element in group VII_{A} or 17 in the IUPAC nomenclature, either undoped or doped with heteroatoms;
E) M¹₃M²₂X₉ or MA₃M²₂X₉ where:
M¹=element in group IA or 1 in the IUPAC nomenclature;
M²=element in group V_{A} or 15 in the IUPAC nomenclature;
X=element in group VII_{A} or 17 in the IUPAC nomenclature; and
MA=[CH3NH3]⁺, CH(NH²)₂]⁺, [CH₆N₃]⁺ or another organic cation, these structures being undoped or doped with heteroatoms.

4. The luminescent solar concentrator according to claim 1, wherein the nanostructures are double perovskites having a composition of the M¹₂M²M³X₆ type where:
M¹=element in group IA or 1 in the IUPAC nomenclature;
M²=elements in group IB or 11 in the IUPAC nomenclature or group IIIA or 13 in the IUPAC nomenclature;
M³=element in group V_{A} or 15 in the IUPAC nomenclature; and
X=element in group VII_{A} or 17 in the IUPAC nomenclature.

5. The luminescent solar concentrator according to claim 4, wherein the perovskite nanostructures are selected from the group consisting of: Cs₂CuSbCl₆, Cs₂CuSbBr₆, Cs₂CuBiBr₆, Cs₂AgSbBr₆, Cs₂AgSbI₆, Cs₂AgBiI₆, Cs₂AuSbCl6, Cs₂AuBiCl6, Cs₂AuBiBr₆, Cs₂InSbCl₆, Cs₂InBiCl₆, Cs₂TlSbBr₆, Cs₂TlSbI₆, and Cs₂TlBiBr₆, said nanostructures may be undoped or doped with heteroatoms.

6. The luminescent solar concentrator according to claim 1, wherein the perovskite nanostructures are structures of the type (C₄N₂H₁₄Br)₄SnX₆ where:
X=Br, I or another element in group VII_{A} or 17 in the IUPAC nomenclature.

7. The luminescent solar concentrator according to claim 1, wherein the body is made of at least one of the following polymers or corresponding copolymers: polyacrylates and polymethylmethacrylates, polyolefins, polyvinyls, epoxy resins, polycarbonates, polyacetates, polyamides, polyurethanes, polyketones, polyesters, polycyanoacrylates, silicones, polyglycols, polyimides, fluorinated and perfluorinated polymers, polycellulose and derivatives such as methyl-cellulose, hydroxymethyl-cellulose, polyoxazine, and silica-based glasses.

8. The luminescent solar concentrator according to claim 1, wherein said luminescent solar concentrator has a sheet-like shape in which the nanostructures are dispersed within a plastics or silica-based glass matrix or deposited in the form of a film on the surfaces thereof.

9. Window for buildings or for moving structures comprising at least a part constructed using a luminescent solar concentrator according to claim 1.
